(19) United States
(12) Patent Application Publication
(10) Pub. No.: US 2017/0069657 A1
(43) Pub. Date: Mar. 9, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Hironobu HAMANAKA, Yokkaichi (JP); Yoshihiro Akutsu, Yokkaichi (JP)

(73) Assignee: Kabushiki Kaisha Toshiba, Minato-ku (JP)

(21) Appl. No.: 15/049,258

(22) Filed: Feb. 22, 2016

Related U.S. Application Data
(60) Provisional application No. 62/216,175, filed on Sep. 9, 2015.

(51) Int. Cl. H01L 27/115; H01L 21/306; H01L 21/28; H01L 21/311; H01L 21/3213; H01L 23/528; H01L 21/3065

(52) U.S. Cl. CPC H01L 27/11582; H01L 23/528; H01L 27/11556; H01L 21/30604; H01L 21/3065; H01L 21/31111; H01L 21/32133; H01L 21/28282; H01L 21/28273

(57) ABSTRACT

According to one embodiment, a semiconductor memory device includes a substrate, a stacked body, a pillar, and memory film. The substrate has a major surface. The stacked body is provided on the major surface. The stacked body includes a plurality of conductive layers arranged in a first direction and separated from each other. The first direction is orthogonal to the major surface. The pillar includes a first portion and a second portion. The first portion extends along the first direction in the stacked body. The second portion is provided in the substrate. The first portion includes a region overlapping one of the conductive layers in a second direction orthogonal to the first direction. The memory film is provided between the stacked body and the pillar. A first length of the region along the second direction is less than a second length of the second portion along the second direction.

### CROSS-REFERENCE TO RELATED APPLICATIONS

This application is based upon and claims the benefit of priority from U.S. Provisional Patent Application 62/216,175, filed on Sep. 9, 2015; the entire contents of which are incorporated herein by reference.

### FIELD

Embodiments described herein relate generally to a semiconductor memory device and a method for manufacturing the same.

### BACKGROUND

Proposed is a three-dimensional structure memory device in which memory cells are arranged three dimensionally. In the manufacture of such a memory device, a stacked body including a plurality of conductive layers is formed on a substrate, and a memory hole is formed passing through the stacked body. A pillar which includes a memory film for recording information and a semiconductor material is formed in this memory hole.

### BRIEF DESCRIPTION OF THE DRAWINGS

FIG. 1 is a perspective view illustrating a semiconductor memory device according to an embodiment;

FIGS. 2 and 3 are cross-sectional views illustrating the semiconductor memory device according to the embodiment;

FIGS. 4 through 6 are process cross-sectional views illustrating the method of manufacturing the semiconductor memory device according to the embodiment;

FIG. 7 is a cross-sectional view illustrating a method of manufacturing the semiconductor memory device according to the embodiment;

FIGS. 8 through 12 are process cross-sectional views illustrating the method of manufacturing the semiconductor memory device according to the embodiment;

FIG. 13 is a cross-sectional view illustrating a semiconductor memory device according to the variation; and

FIGS. 14 through 18 are cross-sectional views of a region corresponding to the region RE1 illustrated in FIG. 9.

### DETAILED DESCRIPTION

According to one embodiment, a semiconductor memory device includes a substrate, a stacked body, a pillar, and memory film. The substrate has a major surface. The stacked body is provided on the major surface. The stacked body includes a plurality of conductive layers arranged in a first direction and separated from each other. The first direction is orthogonal to the major surface. The pillar includes a first portion and a second portion. The first portion extends along the first direction in the stacked body. The second portion is provided in the substrate. The first portion includes a region overlapping one of the conductive layers in a second direction orthogonal to the first direction. The memory film is provided between the stacked body and the pillar. A first length of the region along the second direction is less than a second length of the second portion along the second direction.

Embodiment of the invention will be described hereinafter with reference to the accompanying drawings.

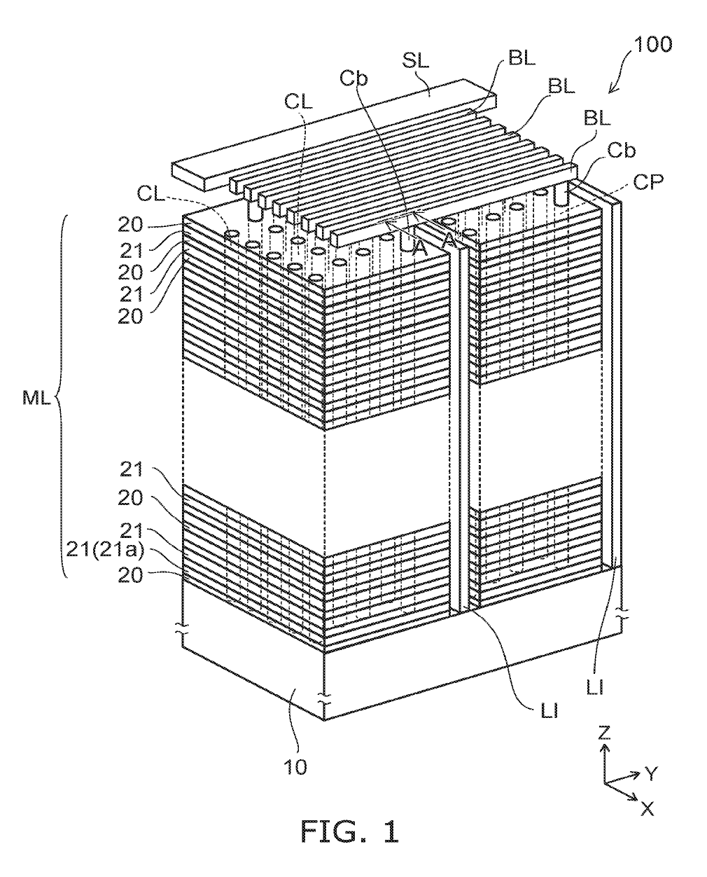

Note that, the drawings are schematic or conceptual. Relations between thicknesses and widths of portions, ratios of sizes among the portions, and the like are not always the same as real ones. Even when the same portions are shown, the portions are sometimes shown in different dimensions and ratios depending on the drawings. Note that in the specification and the drawings, components described with reference to the drawings already referred to are denoted by the same reference numerals and signs. Detailed description of the components is omitted as appropriate. FIG. 1 is a perspective view illustrating a semiconductor memory device according to an embodiment.

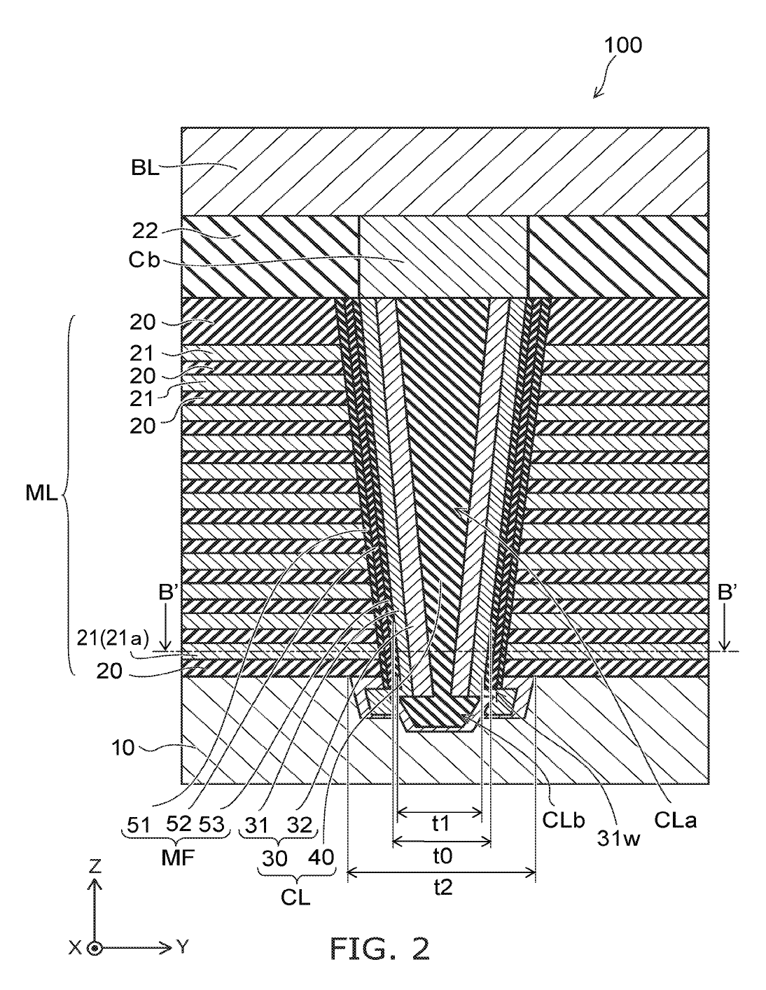

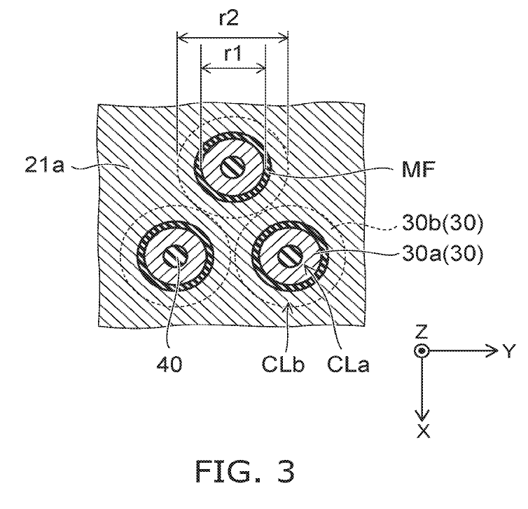

FIGS. 2 and 3 are cross-sectional views illustrating the semiconductor memory device according to the embodiment.

FIG. 2 is a cross-sectional view illustrating a cross section along line A-A′ shown in FIG. 1. FIG. 3 is a cross-sectional view illustrating a cross section along line B-B′ shown in FIG. 2.

As illustrated in FIG. 1, a substrate 10 is provided in a semiconductor device 100 according to the embodiment. The substrate 10 is, for example, a semiconductor substrate containing silicon. On the substrate 10, a pillar CL, a stacked body ML, and a wiring layer LI are provided.

The pillar CL extends in a direction orthogonal to the major surface of the substrate 10, for example, within the stacked body ML. The direction in which the pillar CL extends is Z direction (first direction). The direction orthogonal to the Z direction is Y direction (second direction). The direction orthogonal to the Z direction and the Y direction is X direction (third direction).

The stacked body ML includes a plurality of conductive layers 21 aligned separated from each other in the Z direction. The plurality of conductive layers 21 include a first conductive layer 21a that is closest to the substrate 10 in the Z direction among the plurality of conductive layers 21. For example, the plurality of conductive layers 21 are aligned in the Z direction with insulating bodies placed between the conductive layers 21. The insulating bodies are insulating layers 20, for example. The insulating bodies can be air gaps, for example.

The wiring layer LI extends within the stacked body ML in the X direction and the Z direction. The wiring layer LI includes a conductive portion and an insulating portion. For example, the insulating portion is provided between the stacked body ML and the conductive portion. The wiring layer LI is electrically connected with the substrate 10.

On the stacked body ML, a bit line BL and a source line SL are provided separated from each other. The bit line BL and the source line SL each extend in the Y direction. The pillar CL is electrically connected to the bit line BL via a plug Cb. The wiring layer LI is electrically connected to the source line SL. In FIG. 1, to make the drawing easier to see, insulating members other than the insulating layers 20 are omitted from the illustration. As illustrated in FIG. 2, the plug Cb is provided within an insulating film 22 provided on the stacked body ML.

As illustrated in FIG. 2, the pillar CL includes a core insulating film 40 and a semiconductor film 30. The core insulating film 40 extends in the Z direction within the stacked body ML. The core insulating film 40 overlaps portions of the stacked body ML and the substrate 10 in a direction orthogonal to the Z direction (the Y direction, for example). The semiconductor film 30 is provided between the core insulating film 40 and the stacked body ML and between the core insulating film 40 and the substrate 10. The semiconductor film 30 includes, for example, a first semiconductor film 31 and a second semiconductor film 32. The first semiconductor film 31 is a first semiconductor region, for example. The second semiconductor film 32 is a second semiconductor film, for example.

A memory film MF is provided between the pillar CL and the stacked body ML. The memory film MF includes, for example, a block insulating film 51 (an outside film), a charge storage film 52 (an intermediate film), and a tunnel insulating film 53 (an inside film). The block insulating film 51 is provided between the stacked body ML and the pillar CL. The tunnel insulating film 53 is provided between the block insulating film 51 and the pillar CL. The charge storage film 52 is provided between the block insulating film 51 and the tunnel insulating film 53.

The block insulating film 51 is a film through which a current does not substantially flow even when a voltage within the range of the driving voltage of the semiconductor memory device 100 is applied. The charge storage film 52 is a film with the capability of storing charges. The tunnel insulating film 53 is usually an insulating film. However, when a predetermined voltage within the range of the driving voltage of the semiconductor memory device 100 is applied, a tunnel current flows through the tunnel insulating film 53.

The block insulating film 51 and the tunnel insulating film 53 contain, for example, silicon oxide. The block insulating film 51 and the tunnel insulating film 53 may also contain Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, or AlSiO, for example. The charge storage film 52 contains silicon nitride, for example. The charge storage film 52 may be either a conductive film or an insulating film. The memory film MF may include a floating gate, for example.

The pillar CL includes a first portion CLa and a second portion CLb. The first portion CLa overlaps the stacked body ML in a direction orthogonal to the Z direction (the Y direction, for example). The second portion CLb partially overlaps the substrate 10 in a direction orthogonal to the Z direction (the Y direction, for example). In the second portion CLb, the first semiconductor film 31 includes a portion 31w that extends in a direction orthogonal to the Z direction.

The first portion CLa has a region overlapping one of the plurality of conductive layers 21 in the Y direction. The length of this region in the Y direction is length t0. The length t0 is the maximum length of this region in the Y direction.

For example, there is a region overlapping the first semiconductor layer 21a in the Y direction of the first portion CLa. The length of this region in the Y direction is length t1. The length t1 is the maximum length of this region in the Y direction.

The length of the second portion CLb in the Y direction is length t2. The length t2 is the maximum length of the second portion CLa in the Y direction.

The length t2 is greater than the length t1. The length t2 may be greater than the length t0.

A core insulating film 40 includes an insulating material such as silicon oxide. The core insulating film 40 in the second portion CLb may include a void such as air.

As illustrated in FIG. 3, the semiconductor film 30 includes a portion 30a (first film part) and a portion 30b (second film part). The portion 30a overlaps the first conductive layer 21a in the Y direction. The portion 30b overlaps the substrate 10 and the core insulating film 40 in the Y direction.

The portion 30a has an outer diameter r1. The portion 30b has an outer diameter r2. The cross section of the annular shaped portion 30a is a circular shape, for example. In the embodiment, the cross section of the portion 30a may be a flat circular shape. The cross section of the portion 30b is a circular shape, for example. In the embodiment, the cross section of the portion 30b may be a flat circular shape. The outer diameter r1 of the portion 30a is the effective diameter obtained from the cross section area on the X-Y plane of the pillar CL including the portion 30a, for example. The outer diameter r2 of the portion 30b is the effective diameter obtained from the cross section area on the X-Y plane of the pillar CL including the portion 30b, for example.

For example, the aforementioned cross section area is S, and the aforementioned effective diameter is R, which results in the relationship being S=π(R/2)². From this expression, it is possible to obtain an effective diameter R proportional to the cross section area S. For example, this diameter R corresponds to the outer diameters r1 and r2. The outer diameter r2 is the maximum outer diameter for the portion 30b, for example. The outer diameter r1 is smaller than the outer diameter r2.

Next, a method of manufacturing the semiconductor memory device 100 according to the embodiment is explained.

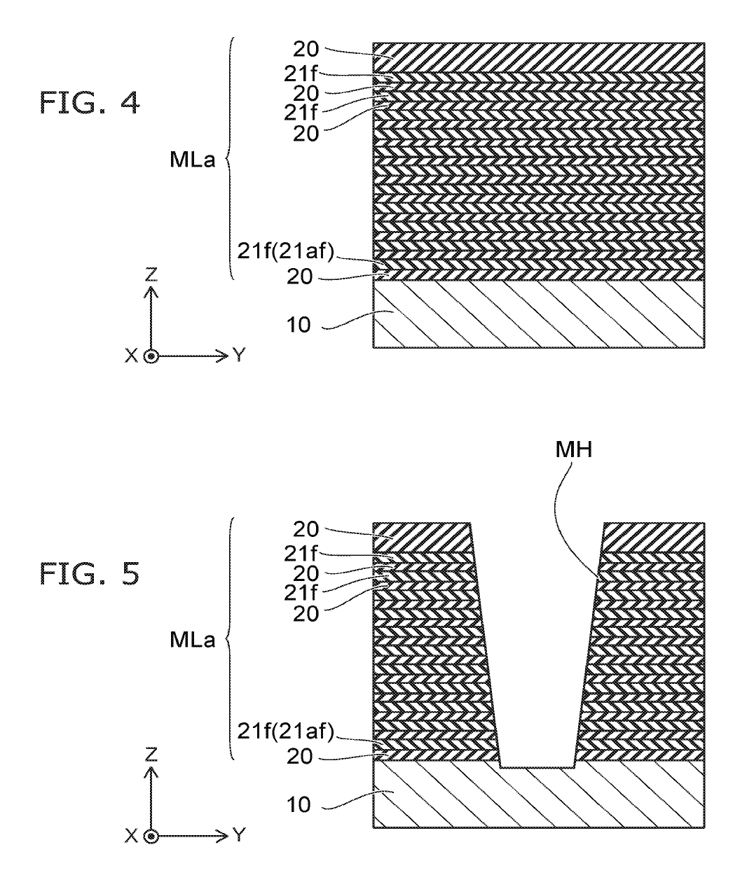

FIGS. 4 through 6 are process cross-sectional views illustrating the method of manufacturing the semiconductor memory device according to the embodiment.

FIG. 7 is a cross-sectional illustrating a method of manufacturing the semiconductor memory device according to the embodiment.

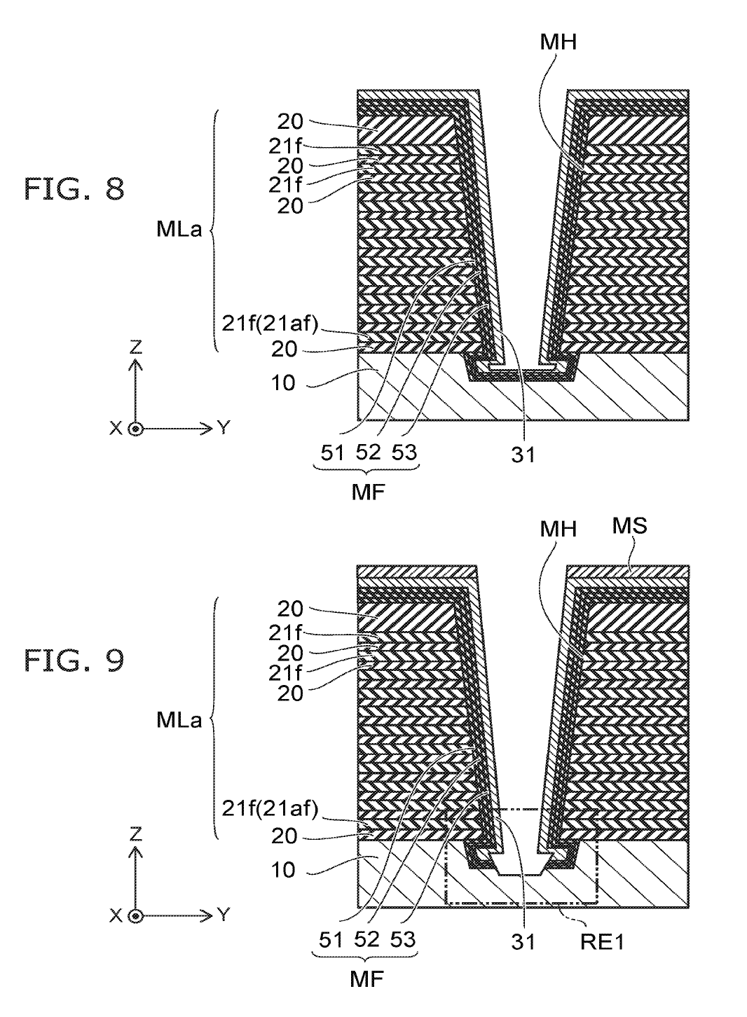

FIGS. 8 through 12 are process cross-sectional views illustrating the method of manufacturing the semiconductor memory device according to the embodiment.

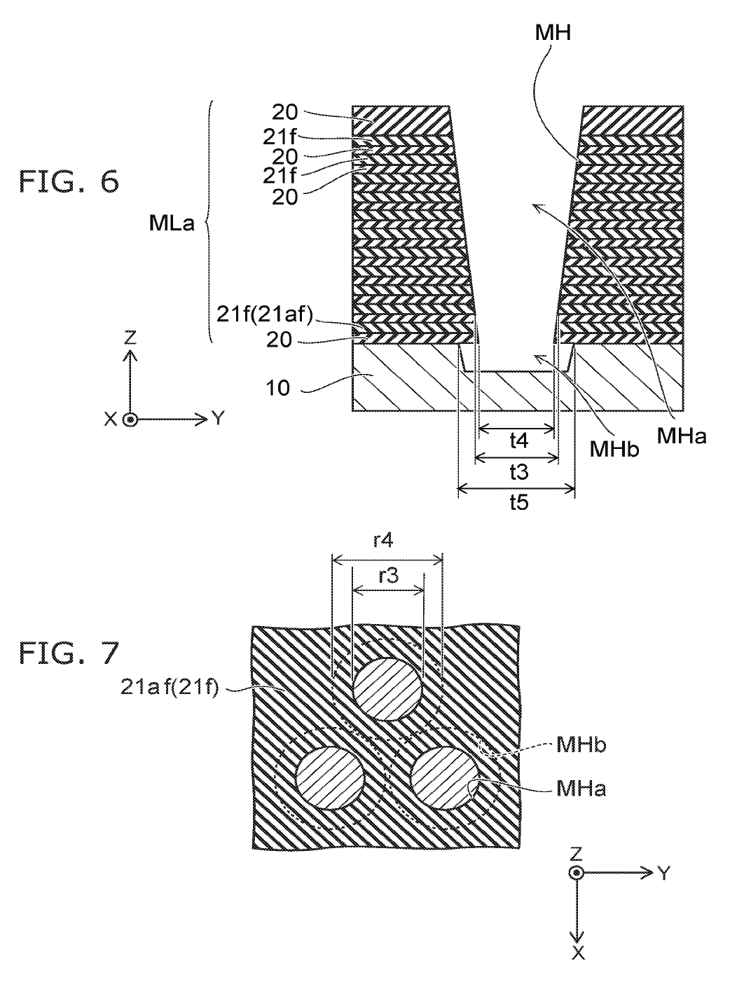

FIG. 7 is a cross-sectional view illustrating a cross section corresponding to the cross section along line B-B′ in FIG. 2 in the process illustrated in FIG. 6.

As illustrated in FIG. 4, the stacked body ML is formed on the substrate 10. The stacked body ML includes a plurality of sacrificial layers 21f aligned separated in the Z direction. The stacked body MLa is formed by alternately stacking sacrificial layers 21f and insulating layers 20, for example. The substrate 10 is, for example, a semiconductor substrate containing silicon. The sacrificial layer 21f is formed of a material containing silicon nitride, for example. The insulating layer 20 is formed of a material containing silicon oxide. The plurality of sacrificial layers 21f include a first sacrificial layer 21af that is the closest sacrificial layer 21f to the substrate 10 in the Z direction.

As illustrated in FIG. 5, anisotropic etching such as reactive ion etching (RIE) is performed on the stacked body MLa. As a result, a memory hole MH passing through the stacked body MLa in the Z direction is formed. The shape of the memory hole MH is a roughly cylindrical shape, for example. The memory hole MH reaches the substrate 10.

As illustrated in FIG. 6, the etching process is performed on the substrate 10 via the memory hole MH. As a result, the space of the memory hole MH in the top layer portion of the substrate 10 is expanded. This etching process is either a dry etching process or a wet etching process, for example. In the Y direction, the region of the memory hole MH overlapping the stacked body MLa is a first region MHa (e.g. first hole). In the Y direction, the region of the memory hole MH overlapping the substrate 10 is a second region MHb (e.g. second hole).

In the Y direction, the length of the first region MHa in the Y direction overlapping one of the plurality of sacrificial layers 21f is length t3. The length t3 is, for example, the maximum length of the first region MHa in the Y direction overlapping one of the plurality of sacrificial layers 21f in the Y direction.

In the Y direction, the length of the first region MHa in the Y direction overlapping the first sacrificial layer 21a is length t4. The length t4 is, for example, the maximum length of the first region MHa in the Y direction overlapping the first sacrificial layer 21af in the Y direction.

In the Y direction, the length of the second region MHb in the Y direction is length t5. The length t5 is, for example, the maximum length of the second region MHb in the Y direction.

The length t5 is greater than the length t4. The length t5 may be greater than the length t3.

As illustrated in FIG. 7, the diameter r3 of the first region MHa overlapping the first sacrificial layer 21af in the Y direction is less than the diameter r4 of the second region MHb.

With the embodiment, a circular cross section is illustrated for the first region MHa, but it may be elliptical. A circular cross section is illustrated for the second region MHb, but it may be elliptical. The diameter r3 of the first region MHa can be defined as the effective diameter obtained from the cross section area on the X-Y plane of the first region MHa. The diameter r4 of the second region MHb can be defined as the effective diameter obtained from the cross section area on the X-Y plane of the second region MHb.

Assuming that the aforementioned cross section is S₂, and the aforementioned effective diameter is R₂, from the relational expression S₂=π(R₂/2)², it is possible to obtain an effective diameter R₂ proportional to the cross section area S₂. The diameter r2 is the maximum diameter of the second region MHb, for example. The difference between the diameter r4 of the second region MHb and the diameter r3 of the first region MHa is preferably equal to or greater than the length in the Y direction of the memory film MF formed in a later process.

As illustrated in FIG. 8, the memory film MF is formed on the inner wall of the memory hole MH. The memory film MF is formed, for example, by stacking the block insulating film 51, the charge storage film 52, and the tunnel insulating film 53 in that order. A first semiconductor film 31 is formed on the inner wall of the memory film MF.

As illustrated in FIG. 9, a mask material MS is formed over the stacked body ML, and using anisotropic etching such as RIE, a portion of the memory film MF and a portion of the first semiconductor film 31 at the bottom of the memory hole MH are removed. As a result, a portion of the substrate 10 is exposed at the bottom of the memory hole MH.

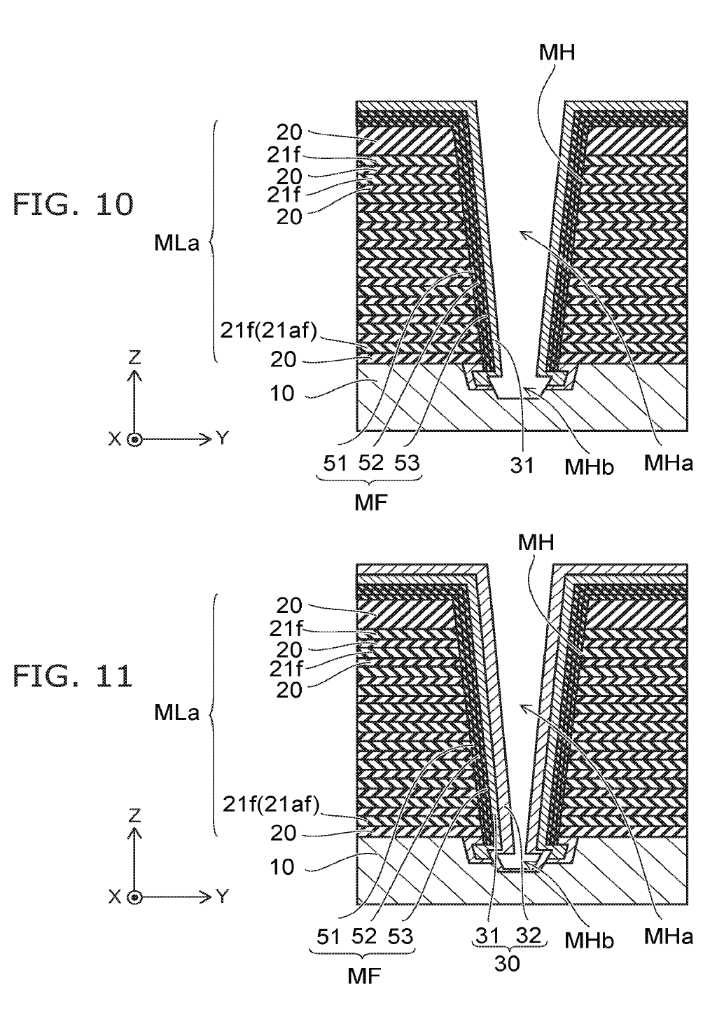

As illustrated in FIG. 10, the etching process is performed on a portion of the memory film MF formed in the second region MHb via the memory hole MH. As a result, the memory film MF covering the side wall of the second region MHb is removed, thereby causing the substrate 10 to be exposed at the side wall of the second region MHb.

As illustrated in FIG. 11, a second semiconductor film 32 is formed on the inner wall of the first semiconductor film 31 and the second region MHb. As a result, the semiconductor film 30 including the first semiconductor film 31 and the second semiconductor film 32 is formed. The semiconductor film 30 is electrically connected to the substrate 10.

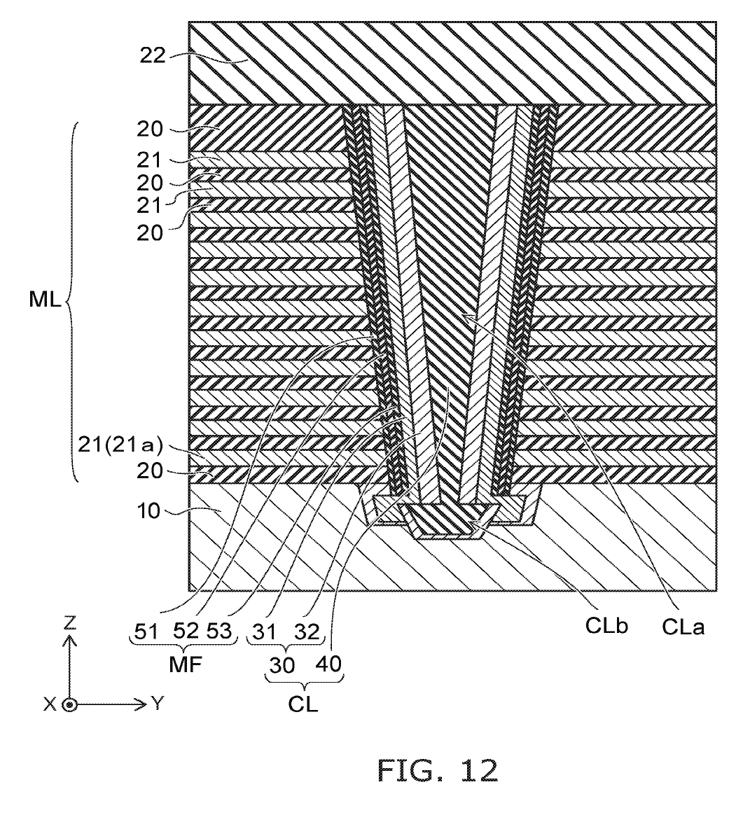

As illustrated in FIG. 12, an insulating material is provided within the memory hole MH. As a result, a core insulating film 40 is formed within the memory hole MH. The first semiconductor film 30 and the memory film MF formed on the top surface of the stacked body ML are removed. As a result, the pillar CL including the core insulating film 40 and the semiconductor film 30 is formed. The insulating film 22 is formed on the stacked body ML, the memory film MF, and the pillar CL.

Thereafter, a wet etching process is performed on the sacrificial layer 21f of the stacked body MLa. As a result, the sacrificial layer 21f is removed. A conductive material such as tungsten is provided in the region from which the sacrificial layer 21f has been removed. As a result, the conductive layer 21 is formed, which brings the stacked body MLa into the stacked body ML. The etching on the sacrificial layer 21f is performed via a groove formed in the stacked body MLa, for example.

As illustrated in FIG. 2, the plug Cb is formed on the pillar CL. The plug Cb passes through the insulating film 22. The bit line BL is formed on the plug Cb and the insulating film 22. The bit line BL extends in the Y direction. In this way, the memory device 100 according to the embodiment is manufactured.

With the embodiment, the etching process on the substrate 10 is performed via the memory hole MH. As a result, the second region MHb is formed within the substrate 10. As a result, it is possible to remove the portion of the substrate 10 which has been damaged by etching in removal of the memory film MF at the bottom of the memory hole MH using RIE. As a result, the contact resistance between the substrate 10 and the pillar CL is reduced. Therefore, the cell current is improved. The yield in the process of removing the memory film MF at the bottom of the memory hole MF is improved. Open defects of the memory hole MH are suppressed.

The second portion CLb of the pillar CL plays the role of anchor. This can suppress, at the time of machining in manufacture, peeling of the stacked body ML (MLa) from the substrate 10.

Next a variation of the embodiment is explained.

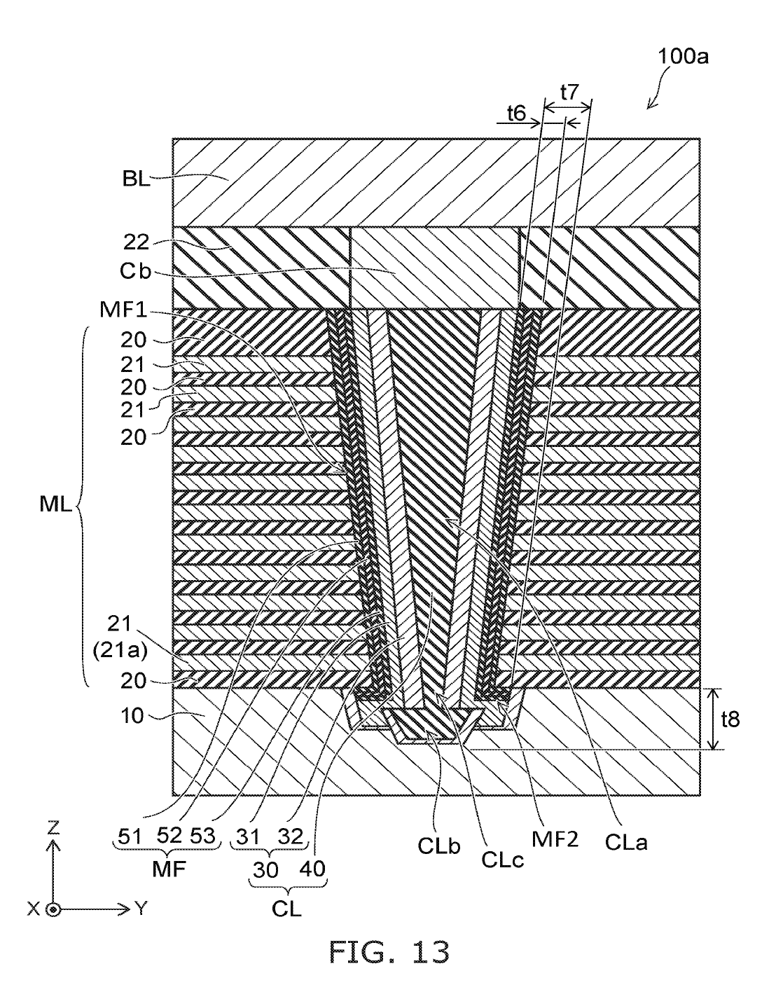

FIG. 13 is a cross-sectional view illustrating a semiconductor memory device according to the variation.

FIG. 13 is a cross-sectional view illustrating a cross section corresponding to the cross section along line A-A′ shown in FIG. 1.

As illustrated in FIG. 13, in the semiconductor memory device 100a according to the variation, the pillar CL includes a first portion CLa, a second portion CLb, and a third portion CLc. The third portion CLc is provided between the first portion CLa and the second portion CUD. The third portion CLc overlaps a portion of the substrate 10 and a portion of the memory film MF in a direction orthogonal to the Z direction (the Y direction, for example).

The memory film MF has a fourth portion MF1 that overlaps the stacked body ML in a direction orthogonal to the Z direction (the Y direction, for example). The length of the fourth portion MF1 in the Y direction is length t6. The memory film MF has a fifth portion (MF2) that overlaps the third portion CLc in a direction orthogonal to the Z direction (the Y direction, for example). The length of the fifth portion (MF2) in the Y direction is length t7. The length t7 is greater than the length t6.

The sum of the length of the second portion CLb in the Z direction and the length of the third portion in the Z direction is length t8. The length of length t8 is two times longer than the length t6.

The other configurations and the manufacturing method are the same as those of the embodiment described above.

Next, description will be given of the etching in the manufacturing process illustrated in FIGS. 9 through 11.

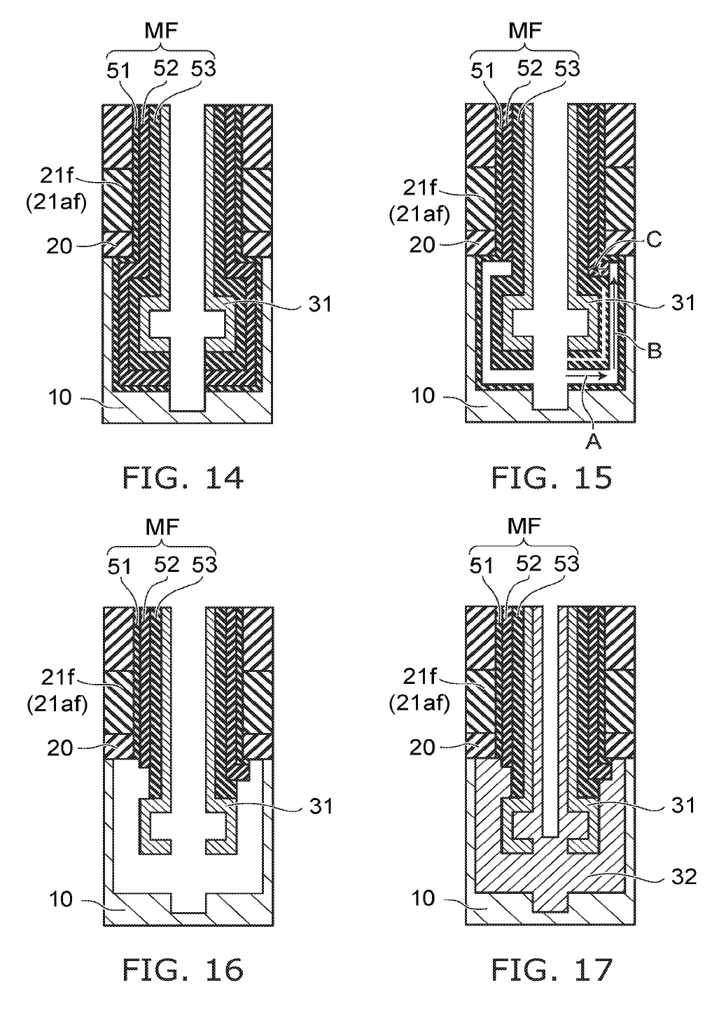

FIGS. 14 through 18 are cross-sectional views of a region corresponding to the region RE1 illustrated in FIG. 9.

As illustrated in FIG. 14, a portion of the first semiconductor film 31 and a portion of the memory film MF at the bottom of the memory hole MH are removed by anisotropic etching such as RIE.

As illustrated in FIG. 15, the etching process is performed on the charge storage film 52 of the memory film MF within the second region MHb. The charge storage film 52 recedes in the order indicated by arrows A through C. A portion of the charge storage film 52 that recedes along the arrow C extends in a direction orthogonal to the Z direction (the Y direction, for example). As a result, variation of the etching on the charge storage film 52 occurs in a direction orthogonal to the Z direction (the Y direction, for example). Thereafter, as illustrated in FIG. 16, etching is performed on the block insulating film 51 and the tunnel insulating film 53 via a space that occurs by removal of the charge storage film 52 in the second region MHb. As a result, the memory film MF that covers the side wall of the second region MHb is removed. As illustrated in FIG. 17, the second semiconductor film 32 is formed on the inner wall of the memory hole MH.

Thereafter, the memory device (100 or 100a) is manufactured by performing manufacturing process described above.

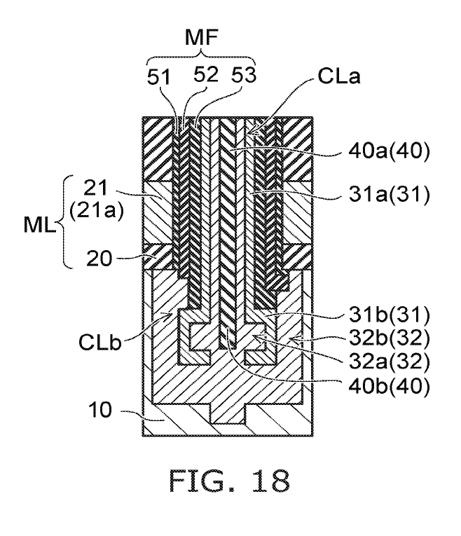

As illustrated in FIG. 18, the pillar CL includes the core insulating film 40, the first semiconductor film 31 and the second semiconductor film 32. The core insulating film 40 extends in the Z direction. The core insulating film 40 includes a first part 41a provided in the first portion CLa, and a second part 41b provided in the second portion CLb. The first semiconductor film 31 includes a third part and fourth part.

The third part 31a provides between the stacked body and the first part 41a. The fourth part 31b provides between the second part 41b and the substrate 10.

The second semiconductor film 32 includes a fifth part 32a and a sixth part 32b. The fifth part 32a provides between the second part 41b and fourth part 31b.

A configuration is considered in which the charge storage film 52 extends linearly along the Z direction. In this case, variation of the etching also occurs in the Z direction. For example, when etching of the charge storage film 52 is performed up to the position of the first sacrificial layer 21af, the memory film MF also recedes to the position of the first sacrificial layer 21af. This brings the semiconductor film 30 formed in a later process and the first conductive layer 21a formed in a later process into contact with each other Therefore, that contact portion becomes defective as a memory cell.

With the embodiment and the variation, in the second region MHb, the charge storage film 52 has a portion that extends in a direction orthogonal to the Z direction (the Y direction, for example). This portion becomes the margin for variation caused by the etching of the memory film MF. In other words, it is possible to suppress variation caused by the etching of the memory film MF in the Z direction.

The embodiments described above can realize a semiconductor memory device for which open defects of the memory hole are suppressed, and the manufacturing method thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a substrate having a major surface;
a stacked body provided on the major surface, the stacked body including a plurality of conductive layers arranged in a first direction and separated from each other, the first direction being orthogonal to the major surface;
a pillar including a first portion, a second portion and a third portion, the first portion extending in the first direction in the stacked body, the second portion being provided in the substrate, the first portion including a region overlapping one of the conductive layers in a second direction orthogonal to the first direction, the third portion being provided between the first portion and the second portion; and
a memory film provided between the stacked body and the pillar, the memory film including a fourth portion and a fifth portion, the fourth portion overlapping the first portion and the stacked body in the second direction, the fifth portion overlapping the third portion and substrate in the second direction,
a first length of the region in the second direction being less than a second length of the second portion in the second direction,
a fifth length of the fifth portion in the second direction being greater than a fourth length of the fourth portion in the second direction.

2. The device according to claim 1, wherein
the one of conductive layer is closest to the substrate among the conductive layers.

3. The device according to claim 1, wherein
a length two times the fourth length is less than a sum of a second length of the second portion along the second direction and a third length of the third portion along the second direction.

4. The device according to claim 1, wherein
the pillar includes:
a core insulating film extending in the first direction, and
a semiconductor film including a first film part and a second film part, the first film part being provided between the core insulating film and the stacked body, the second film part being provided between the core insulating film and the substrate, and
a first outer diameter of the first film part along the second direction is less than a second outer diameter of the second film part along the second direction.

5. A semiconductor memory device comprising:
a substrate having a major surface;
a stacked body provided on the major surface, the stacked body including a plurality of conductive layers arranged in a first direction and separated from each other, the first direction being orthogonal to the major surface;
a pillar including a first portion, a second portion, a core insulating film, a first semiconductor region and a second semiconductor region, the first portion extending in the first direction in the stacked body, the second portion being provided in the substrate, the first portion including a region overlapping one of the conductive layers in a second direction orthogonal to the first direction, the core insulating film extending in the first direction, the core insulating film including a first part provided in the first portion, and a second part provided in the second portion; and
a memory film provided between the stacked body and the pillar, the memory film including a fourth portion and a fifth portion, the fourth portion overlapping the first portion and the stacked body in the second direction, the fifth portion overlapping the third portion and substrate in the second direction,
a first length of the region along the second direction being less than a second length of the second portion along the second direction,
the first semiconductor region including a third part provided between the stacked body and the first part, and the fourth part provided between the substrate and the second part,
the second semiconductor region including a fifth part provided between the substrate and the fourth part and, the sixth part provided between the second part and the fifth part.

6. The device according to claim 5, wherein
the one of conductive layer is closest to the substrate among the conductive layers.

7. The device according to claim 5, wherein
a length two times the fourth length is less than a sum of a second length of the second portion along the second direction and a third length of the third portion along the second direction.

8. The device according to claim 5, wherein
the first semiconductor region includes a portion extending along a direction orthogonal to the first direction in the second portion.

9. The device according to claim 5, wherein
the first semiconductor region is electrically connected to the substrate via the second semiconductor region.

10. The device according to claim 5, further comprising:
a wiring layer extending along the first direction and along a third direction in the stacked body, the third direction being orthogonal to the first direction and the second direction,
the first semiconductor region being electrically connected to the wiring layer via the second semiconductor region.

11. A method of manufacturing a semiconductor memory device, comprising:
forming a stacked body on a substrate, the stacked body including a plurality of first layers provided separated from each other along a first direction;
forming a first region passing through the stacked body along the first direction,
firstly etching the substrate via the first region to form a second region in the substrate,
forming a memory film on inner walls of the first region and the second region,
forming a first semiconductor film on an inner wall of the memory film,
removing the memory film formed at a bottom of the second hole and removing the first semiconductor film formed at the bottom of the second region,
secondly etching the memory film in the second region; and
forming a second semiconductor film in the first region and the second region.

12. The method according to claim 11, wherein
the firstly etching includes dry etching.

13. The method according to claim 11, wherein
the firstly etching includes wet etching.

14. The method according to claim 11, wherein
the forming a memory film includes:
forming an outside film on the inner walls of the first region and the second region,
forming an intermediate film on an inner wall of the outside film, and
forming an inside film on an inner wall of the intermediate film, and
the secondly etching includes:
etching a portion of the intermediate film via the second region, and
etching a portion of the inside film and a portion of the outside film via the second region.
